(19) United States
(12) Patent Application Publication
(10) Pub. No.: US 2003/0039099 A1
(43) Pub. Date: Feb. 27, 2003

(54) Shell assembly of computer server

(76) Inventor: Evelyn Chen, Tai-Shan Shiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/933,183

(22) Filed: Aug. 21, 2001

(51) Int. Cl. H05K 5/00

(52) U.S. Cl. 361/727; 361/724

(57) ABSTRACT

A shell assembly for computer server comprises a retaining frame having a plurality of sliding rails therein, a serve module and a power supply. The retaining frame can be fixed to computer chassis of various sizes. The serve module is slidably fit with the sliding rails on both sides thereof and the power supply is used to provide electric power to the serve module. The serve module has a plurality of insertion ports at front side thereof to facilitate the operations of external connection, series connection, expansion and upgrading for the serve module.

### FIELD OF THE INVENTION

The present invention relates to a shell assembly for a computer server, especially to a shell assembly for computer server adapted to computer chassis of various sizes, whereby the computer server can be connected to Internet and easily interconnected, expanded, upgraded, maintained or replaced.

### BACKGROUND OF THE INVENTION

FIGS. 1 and 2 show a conventional retaining structure for computer server and chassis 11. The retaining structure comprises a retaining frame 10 having two sliding grooves 101 and 102 on both sides thereof as shown in FIG. 2. The sliding grooves 101 and 102 are slidably fit with sliding blocks 111 of the chassis 11.

The retaining frame 10 has an assembling unit 12 at front side thereof and the assembling unit 10 is used to accommodate hard disk driver, floppy disk driver and power supply (not shown). The retaining frame 10 has a server module 13 at rear side thereof. The server module 13 has a plurality of connection slots 131 and radiating fans 132 at rear side thereof. The radiating fans 132 are used to remove heat of the server module 13. The connection slots 131 facilitate the connection of transmission cables 14 to the server module 13 as shown in FIG. 2, whereby the server module 13 can be in series connection to another server module 13.

However, the chassis 11 is generally of rectangular shape and the connection slots 131 of the server module 13 are arranged in an inward position of the assembling unit 10. The connection, expansion, upgrading, maintenance and replacement of the server module 13 are hindered.

Moreover, the assembling unit 10 and the server module 13 should be removed when the server module 13 needs operation of connection, expansion, upgrading, maintenance and replacement. Alternatively, the chassis 11 should preserve considerable space for the connection, expansion, upgrading, maintenance and replacement of the server module 13.

Moreover as shown in FIG. 2, the transmission cables 14 at rear side of the server module 13 tend to have twisting problem due to lack of means to regulate those transmission cables 14. As a result, the transmission cables 14 may have wrong insertion into the connection slots 131.

### SUMMARY OF THE INVENTION

It is an object of the present invention to provide a shell assembly for computer server adapted to computer chassis of various sizes. The operations of external connection, series connection, expansion and upgrading thereof do not require large space.

It is another object of the present invention to provide a shell assembly for computer server to prevent twisting problem of transmission cables and wrong insertion of the transmission cables into the connection slots.

To achieve above objects, the present invention provides a shell assembly for computer server having a retaining frame having a plurality of sliding rails therein, a serve module and a power supply. The serve module and the power supply are arranged within the retaining frame and the retaining frame is fixed to a chassis. The retaining frame has a plurality of first connectors and radiating fans at rear side thereof. The first connectors are connected to a second connector of the serve module and a third connector of the power supply. The retaining frame has a plurality of sliding tracks on inner wall thereof for facilitating the sliding of the serve module and the power supply into and out of the retaining frame. The radiating fans is used to prevent over temperature of the serve module and the power supply.

The various objects and advantages of the present invention will be more readily understood from the following detailed description when read in conjunction with the appended drawing, in which:

### BRIEF DESCRIPTION OF DRAWING

FIG. 1 shows a perspective view of prior art retaining structure for computer server;

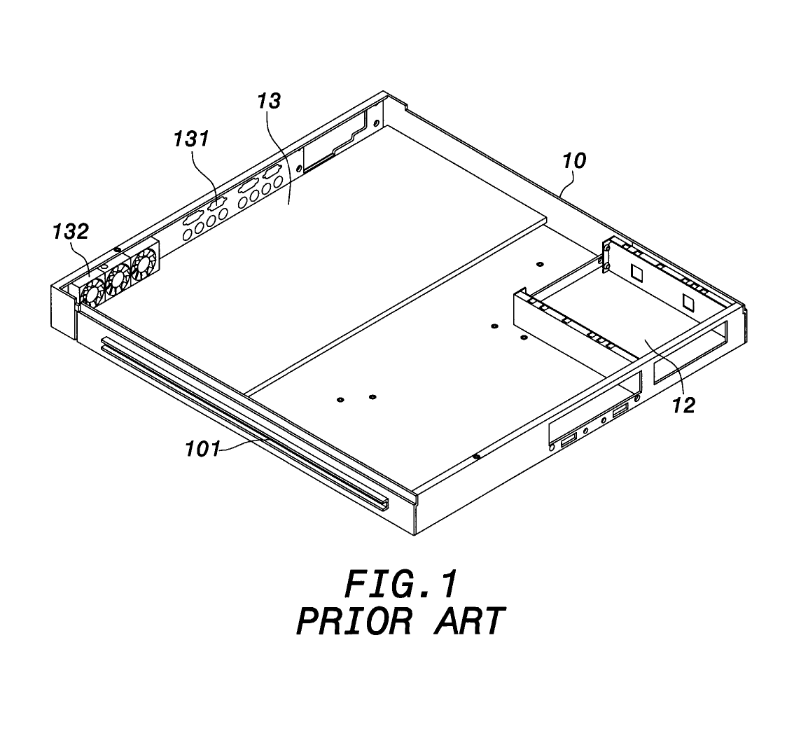

FIG. 2 shows a sectional view of prior art retaining structure for computer server and a chassis;

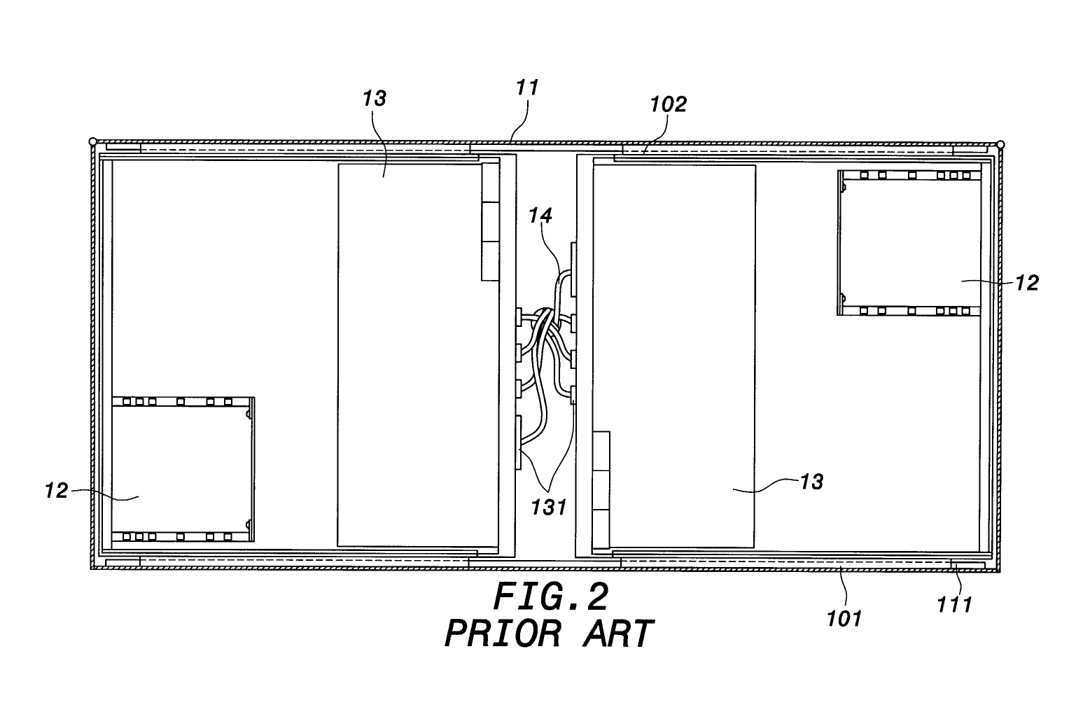

FIG. 3 shows an exploded view of the present invention;

FIG. 4 shows a perspective view of the present invention;

FIG. 5 shows a sectional view of the present invention;

FIG. 6 shows a perspective view of another preferred embodiment of the present invention; and

FIG. 7 shows a perspective view of still another preferred embodiment of the present invention.

### DETAILED DESCRIPTION OF THE INVENTION

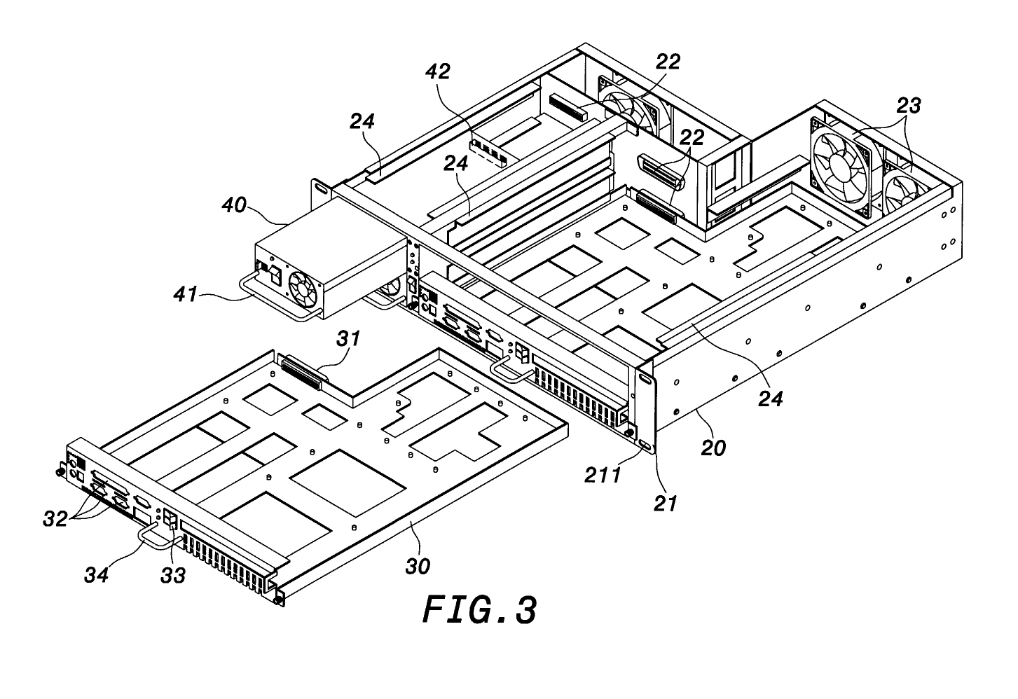

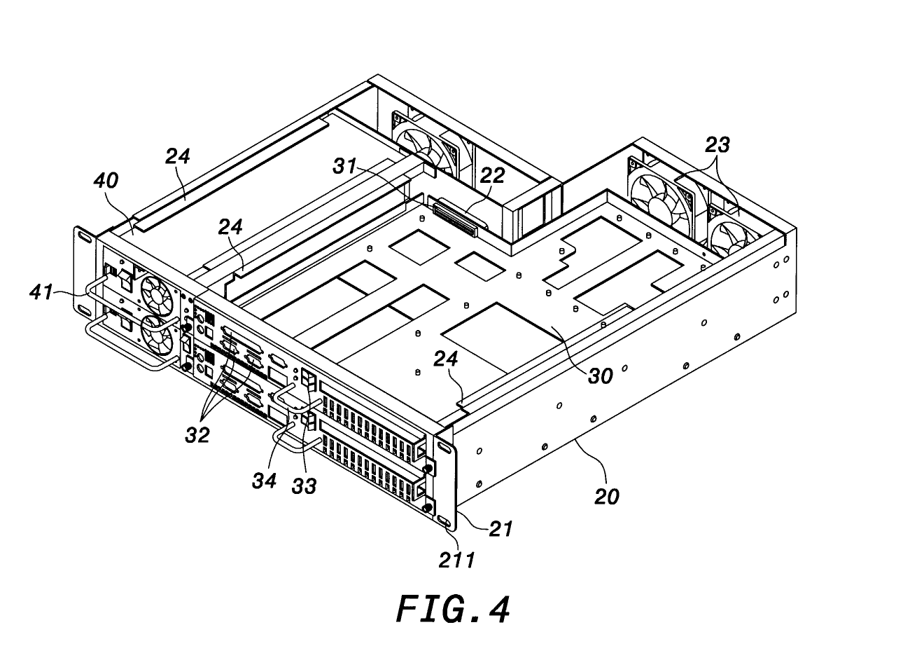

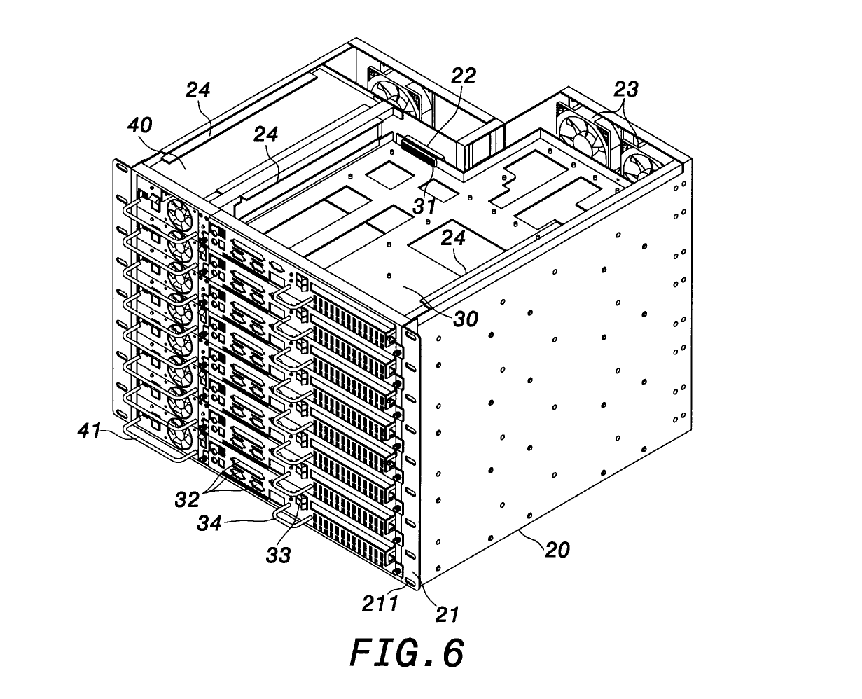

With reference now to FIGS. 3 to 7, the present invention provides a shell assembly for computer server adapted to computer chassis of various sizes, whereby the computer server can be connected to Internet and easily interconnected, expanded, upgraded, maintained or replaced. The shell for computer server comprises a retaining frame 20, a serve module 30 and a power supply 40.

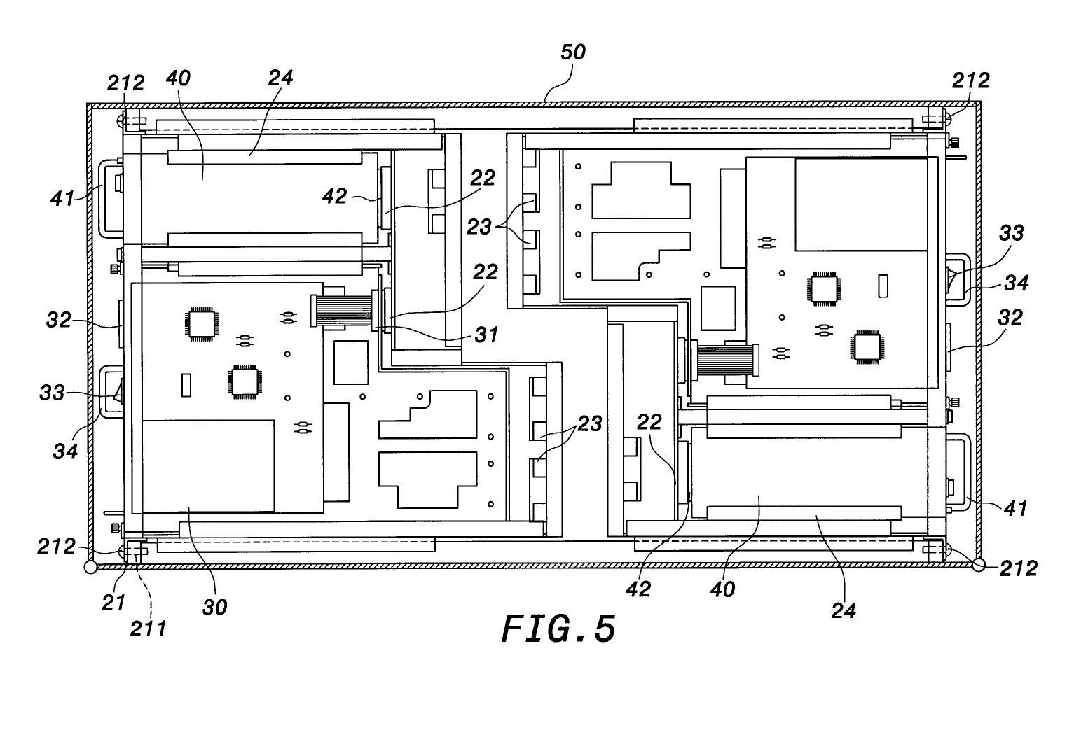

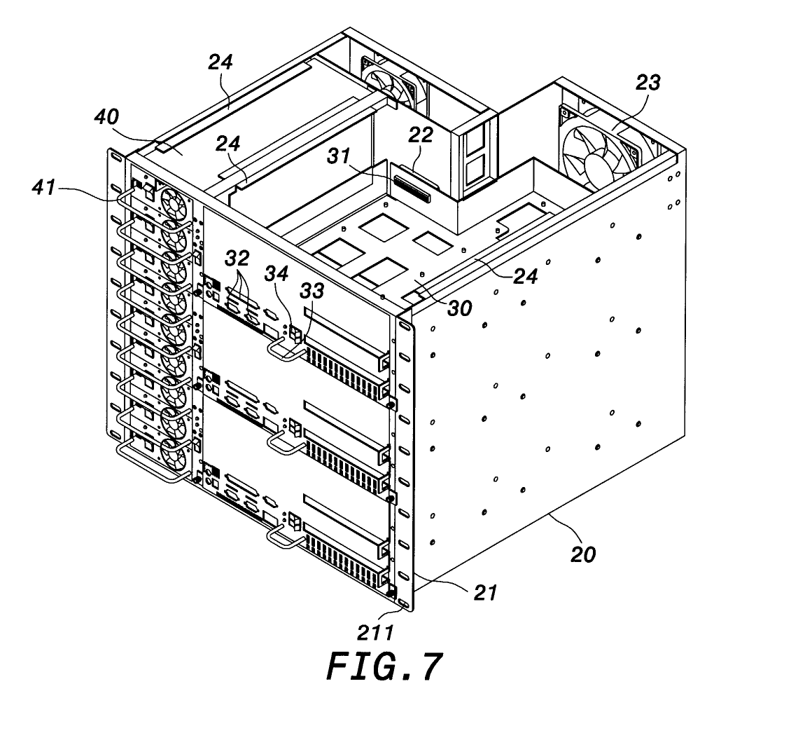

The retaining frame 20 is made of metal and is fixedly arranged on computer chassis 50 of various sizes as shown in FIGS. 5 and 7. The overall length of the retaining frame 20 can be increased or decreased according to user's need as shown in FIGS. 3 to 6. The retaining frame 20 has two lugs 21 at front side thereof and each lug 21 has a plurality of retaining holes 211. The retaining holes 211 can be screwed by corresponding fixing elements 212 to fix the retaining frame 20 on the computer chassis 50. The fixing element 212 can be, for example, screw, pin or rivet.

The retaining frame 20 has a plurality of first connectors 22 and radiating fans 23 at rear side thereof. The first connectors 22 are connected to a second connector 31 of the serve module 30 and a third connector 42 of the power supply 40. The retaining frame 20 has a plurality of sliding tracks 24 on inner wall thereof for facilitating the sliding of the serve module 30 and the power supply 40 into and out of the retaining frame 20. The radiating fans 23 is used to remove the heat generated by the serve module 30 and the power supply 40 and prevents over temperature of the serve module 30 and the power supply 40.

The serve module 30 has a plurality of interface units accessible for user (not shown) by which the serve module 30 has expanded and versatile functions such as Internet connection. Moreover, the serve module 30 has a plurality of insertion ports 32, switches 33 and a first U-shaped handle 34 at front side thereof. The plurality of insertion ports 32 provides the serve module 30 with functions of external connection, series connection, expansion and upgrading. The plurality of switches 33 is used to turn on or turn off the serve module 30 to save power consumption. The first U-shaped handle 34 facilitates the user to pull the serve module 30 out of the retaining frame 20 for repairing or replacing the interface units.

The power supply 40 is slidably fit with the sliding tracks 24 within the retaining frame 20 and used to provide electrical power to the serve module 30. The power supply 40 has a second U-shaped handle 41 at front side thereof. The second U-shaped handle 41 facilitates the user to pull the power supply 40 out of the retaining frame 20 for repairing or replacing the interface units.

In the present invention, the retaining frame 20 is provided with a plurality of sliding tracks 24 on inner wall thereof for facilitating the sliding of the serve module 30 and the power supply 40 into and out of the retaining frame 20. The serve module 30 has a plurality of insertion ports 32, switches 33 and a first U-shaped handle 34 at front side thereof; and the power supply 40 has a second U-shaped handle 41 at front side thereof Therefore, it is convenient for user to perform operations of external connection, series connection, expansion and upgrading for the serve module 30 and the power supply 40. The used space is not wasted and the insertion ports 32 can be prevented from wrong insertion. Moreover, it is not necessity for the insertion ports 32 to be arranged at rear side of the retaining frame 20, the external connection, series connection, expansion and upgrading of the serve module 30 are simplified.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim

1. A shell assembly for computer server, mainly comprising
a retaining frame having a plurality of sliding rails therein
a serve module slidably fit with the sliding rails on both sides thereof; the serve module having a plurality of insertion ports and switches on one side thereof; and
a power supply slidably fit with the sliding rails on both sides thereof; the power supply used to provide electric power to the serve module.

2. The shell assembly for computer server as in claim 1, wherein the retaining frame has two lugs at front side thereof to fix the retaining frame on the computer chassis.

3. The shell assembly for computer server as in claim 2, wherein the retaining frame has a plurality of retaining holes screwed by corresponding fixing elements.

4. The shell assembly for computer server as in claim 3, wherein the fixing element is screw, pin or rivet.

5. The shell assembly for computer server as in claim 1, wherein the retaining frame has a plurality of connectors and radiating fans at rear side thereof, the connectors of the retaining frame being connected to corresponding connectors of the serve module and the power supply.

6. The shell assembly for computer server as in claim 1, wherein the serve module has a plurality of interface units accessible for user.

7. The shell assembly for computer server as in claim 1, wherein the serve module has a U-shaped handle at front side thereof.

8. The shell assembly for computer server as in claim 1, wherein the power supply has a U-shaped handle at front side thereof.
